(19) United States
(12) Patent Application Publication
(10) Pub. No.: US 2016/0072013 A1
(43) Pub. Date: Mar. 10, 2016

(54) SEMICONDUCTOR LIGHT EMITTING DEVICE

(71) Applicant: Kabushiki Kaisha Toshiba, Minato-ku (JP)

(72) Inventor: Yoshiaki SUGIZAKI, Fujisawa (JP)

(73) Assignee: Kabushiki Kaisha Toshiba, Minato-ku (JP)

(21) Appl. No.: 14/640,352

(22) Filed: Mar. 6, 2015

(30) Foreign Application Priority Data
Sep. 9, 2014 (JP) 2014-183632

(51) Int. Cl. H01L 33/22; H01L 33/46

(52) U.S. Cl. CPC H01L 33/22; H01L 33/46

(57) ABSTRACT

According to one embodiment, a semiconductor light emitting device includes a stacked body, a first electrode, a second electrode, a first interconnection section, a second interconnection section, an insulating layer, a first transmissive layer, a first reflection film, and a second transmissive layer. The stacked body includes a first layer having a rough surface, a second layer, and a light emitting layer. The first transmissive layer is provided on a side of the stacked body. The first reflection film is provided between the first transmissive layer and the insulating layer. The second transmissive layer is provided on the rough surface of the first layer and on the first transmissive layer, and includes a plurality of particles. Surface roughness of a surface on the second transmissive layer side of the first transmissive layer is smaller than surface roughness of the rough surface of the first layer.

### CROSS-REFERENCE TO RELATED APPLICATION

This application is based upon and claims the benefit of priority from Japanese Patent Application No. 2014-183632, filed on Sep. 9, 2014; the entire contents of which are incorporated herein by reference.

### FIELD

Embodiments described herein relate generally to a semiconductor light emitting device.

### BACKGROUND

As a semiconductor light emitting device that emits visible light such as white light and lights in other wavelength bands using a combination of LED (Light Emitting Diode) elements and fluorescent materials, a semiconductor light emitting device of a chip-size package structure has been proposed. In such a semiconductor light emitting device, it is desired to improve light extraction efficiency.

### BRIEF DESCRIPTION OF THE DRAWINGS

FIG. 1 is a schematic sectional view of a semiconductor light emitting device of an embodiment;

FIGS. 2A and 2B are schematic plan views of the semiconductor light emitting device of the embodiment;

FIG. 3 is an enlarged sectional view of the semiconductor light emitting device of the embodiment;

FIG. 4 is an enlarged sectional view of the semiconductor light emitting device of the embodiment;

FIG. 5 is an enlarged sectional view of the semiconductor light emitting device of the embodiment;

FIG. 6 is an enlarged sectional view of the semiconductor light emitting device of the embodiment;

FIG. 7 is an enlarged sectional view of the semiconductor light emitting device of the embodiment; and

FIG. 8 is an enlarged sectional view of the semiconductor light emitting device of the embodiment.

### DETAILED DESCRIPTION

According to one embodiment, a semiconductor light emitting device includes a stacked body, a first electrode, a second electrode, a first interconnection section, a second interconnection section, an insulating layer, a first transmissive layer, a first reflection film, and a second transmissive layer. The stacked body includes a first layer having a rough surface, a second layer, and a light emitting layer provided between the first layer and the second layer. The first electrode is provided on the first layer. The second electrode is provided on the second layer. The first interconnection section is provided on an opposite side of the rough surface in the stacked body and is connected to the first electrode. The second interconnection section is provided on the opposite side of the rough surface in the stacked body and is connected to the second electrode. The insulating layer is provided on a side surface of the first interconnection section and a side surface on the second interconnection section. The first transmissive layer is provided on a side of the stacked body. The first reflection film is provided between the first transmissive layer and the insulating layer. The second transmissive layer is provided on the rough surface of the first layer and on the first transmissive layer, and includes a plurality of particles. Surface roughness of a surface on the second transmissive layer side of the first transmissive layer is smaller than surface roughness of the rough surface of the first layer.

Embodiments are described below with reference to the drawings. Note that, in the figures, the same components are denoted by the same reference numerals and signs.

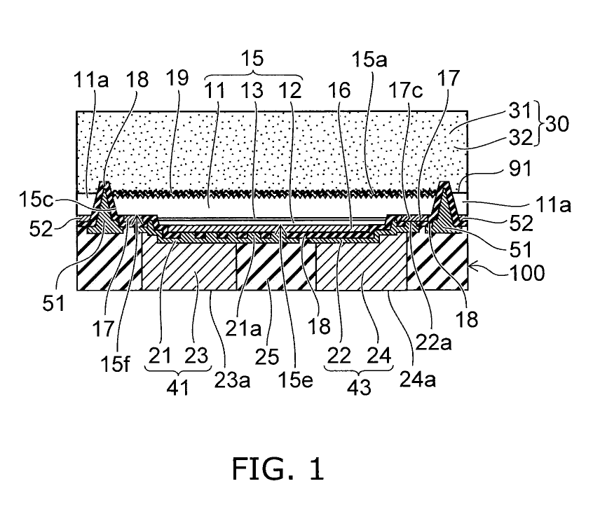

FIG. 1 is a schematic sectional view of a semiconductor light emitting device of an embodiment.

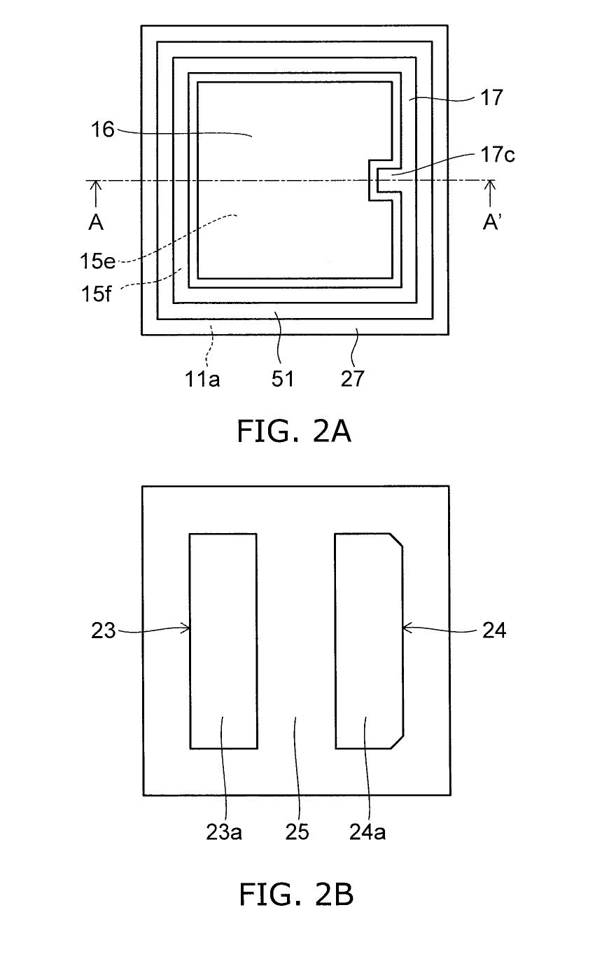

FIG. 2A is a schematic plan view showing an example of a plane layout of a part of components in the semiconductor light emitting device of the embodiment. FIG. 1 corresponds to an A-A′ cross section in FIG. 2A.

FIG. 2B is a schematic plan view of a mounting surface of the semiconductor light emitting device of the embodiment (the lower surface of the semiconductor light emitting device shown in FIG. 1).

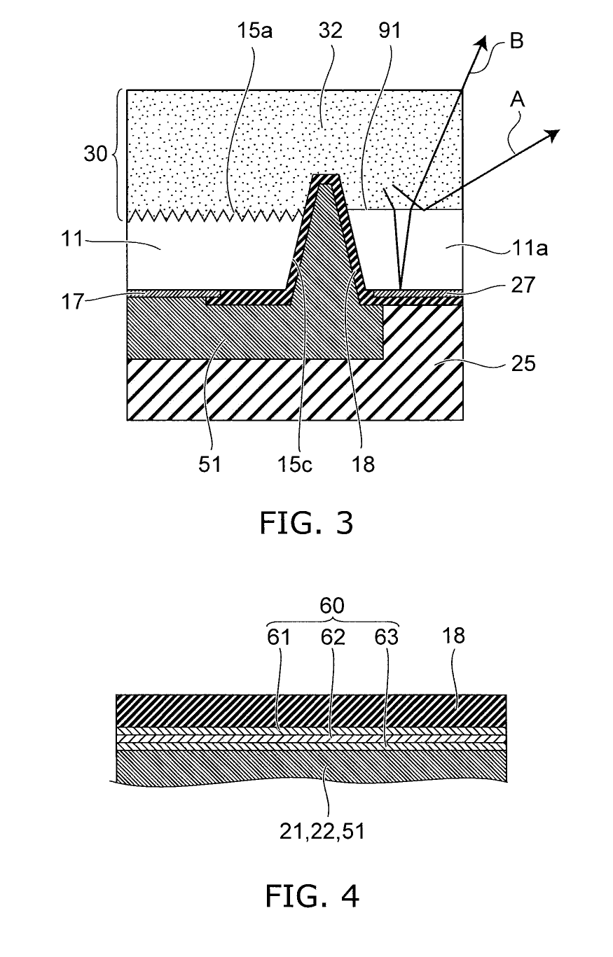

FIG. 3 is an enlarged sectional view of a side surface 15c of a semiconductor layer 11 and a region adjacent to the side surface 15c in the semiconductor light emitting device shown in FIG. 1. In FIG. 3, an insulating film 19 on a rough surface 15a shown in FIG. 1 is not shown.

The semiconductor light emitting device of the embodiment includes a supporting body 100, a fluorescent material layer 30, and a stacked body provided between the supporting body 100 and the fluorescent material layer 30 and including the semiconductor layer 15.

The semiconductor layer 15 includes a first layer including a first semiconductor layer 11, a second layer including a second semiconductor layer 12, and a light emitting layer 13 provided between the first layer and the second layer.

The first semiconductor layer 11 and the second semiconductor layer 12 contain, for example, gallium nitride. The first semiconductor layer 11 includes, for example, a foundation buffer layer and an n-type GaN layer. The second semiconductor layer 12 includes, for example, a p-type GaN layer. The light emitting layer 13 includes materials that emit blue light, violet light, blue-violet light, ultraviolet light, and the like. A light-emission peak wavelength of the light emitting layer 13 is, for example, 430 to 470 nm.

The first semiconductor layer 11 includes the rough surface (a first surface) 15a. The rough surface 15a includes a plurality of micro-irregularities. The opposite side of the rough surface 15a in the first semiconductor layer 11 is processed into a convexo-concave shape. The light emitting layer 13 and the second semiconductor layer 12 are provided in a convex portion of the first semiconductor layer 11. The light emitting layer 13 is provided between the convex portion of the first semiconductor layer 11 and the second semiconductor layer 12. In a concave portion of the first semiconductor layer 11, the light emitting layer 13 and the second semiconductor layer 12 are not provided.

Therefore, the semiconductor layer 15 includes a portion (a light emitting region) 15e including the light emitting layer 13 and a portion (a non-light emitting region) 15f not including the light emitting layer 13. The portion 15e including the light emitting layer 13 is a portion where the light emitting layer 13 is stacked in the semiconductor layer 15. The portion 15f not including the light emitting layer 13 is a portion where the light emitting layer 13 is not stacked in the semiconductor layer 15. The portion 15e including the light emitting layer 13 indicates a region formed in a stacked structure capable of extracting emitted light of the light emitting layer 13 to the outside.

A p-side electrode 16 is provided on the surface of the second semiconductor layer 12 in the portion 15e including the light emitting layer 13. An n-side electrode 17 is provided on the surface of the first semiconductor layer 11 of the portion 15f not including the light emitting layer 13.

In the example shown in FIG. 2A, the portion 15f not including the light emitting layer 13 surrounds the portion 15e including the light emitting layer 13. The n-side electrode 17 surrounds the p-side electrode 16.

The area of the portion 15e including the light emitting layer 13 is larger than the area of the portion 15f not including the light emitting layer 13. The area of the p-side electrode 16 provided on the surface of the portion 15e including the light emitting layer 13 is larger than the area of the n-side electrode 17 provided on the surface of the portion 15f not including the light emitting layer 13. Consequently, a wide light emitting surface is obtained. It is possible to increase an optical output.

As shown in FIG. 2A, the n-side electrode 17 includes, for example, four linear sections. In one linear section among the four linear sections, a contact section 17c projecting in the width direction of the linear section is provided. As shown in FIG. 1, a via 22a of an n-side interconnection layer 22 is connected to the surface of the contact section 17c.

An electric current is supplied to the light emitting layer 13 through the p-side electrode 16 and the n-side electrode 17. The light emitting layer 13 emits light. The light emitted from the light emitted layer 13 is made incident on the fluorescent material layer 30 from the first surface (the rough surface) 15a side of the first semiconductor layer 11.

The supporting body 100 is provided on the opposite side (a second surface side) of the rough surface 15a in the semiconductor layer 15. A light emitting element including the semiconductor layer 15, the p-side electrode 16, and the n-side electrode 17 is supported by the supporting body 100.

The fluorescent material layer 30 is provided on the rough surface 15a side of the semiconductor layer 15 as an optical layer that imparts a desired optical characteristic to emitted light of the semiconductor layer 15. The fluorescent material layer 30 includes a plurality of fluorescent materials 31 as optical particles. The fluorescent materials 31 are excited by the emitted light of the light emitting layer 13 to emit light having wavelength different from the wavelength of the emitted light.

The plurality of fluorescent materials 31 are integrated by a transmissive layer (a second transmissive layer) 32. The transmissive layer 32 transmits the emitted light of the light emitting layer 13 and the emitted light of the fluorescent materials 31. “Transmit” is not limited to transmission at transmittance of 100% and includes absorption of a part of light.

The opposite side (the second surface side) of the rough surface 15a in the semiconductor layer 15, the p-side electrode 16, and the n-side electrode 17 are covered with an insulating film 18. The insulating film 18 is an inorganic insulating film such as a silicon oxide film. The insulating film 18 is also provided on the side surface of the light emitting layer 13 and the side surface of the second semiconductor layer 12 and covers the side surface of the light emitting layer 13 and the side surface of the second semiconductor layer 12.

The insulating film 18 is also provided on the side surface 15c extending from the rough surface 15a in the first semiconductor layer 11 and covers the side surface 15c.

On the insulating film 18, a p-side interconnection layer 21 and an n-side interconnection layer 22 are provided to be separated from each other. In the insulating film 18, a plurality of first openings leading to the p-side electrode 16 and a second opening leading to the contact section 17c of the n-side electrode 17 are formed. Note that the first openings may be larger one opening.

The p-side interconnection layer 21 is provided on the insulating film 18 and on the inside of the first opening. The p-side interconnection layer 21 is electrically connected to the p-side electrode 16 via a plurality of vias 21a provided in the first opening.

The n-side interconnection layer 22 is provided on the insulating film 18 and on the inside of the second opening. The n-side interconnection layer 22 is electrically connected to the contact section 17c of the n-side electrode 17 via the via 22a provided in the second opening.

The p-side interconnection layer 21 and the n-side interconnection layer 22 occupy most of a region on the second surface side of the semiconductor layer 15 and expand on the insulating film 18. The p-side interconnection layer 21 is connected to the p-side electrode 16 via the plurality of vias 21a. A reflection film 51 covers the side surface 15c of the semiconductor layer 15 via the insulating film 18. The reflection film 51 is not in contact with the side surface 15c and is not electrically connected to the semiconductor layer 15. The reflection film 51 is separated from the p-side interconnection layer 21 and the n-side interconnection layer 22. The reflection film 51 is a metal film having reflectivity to the emitted light of the light emitting layer 13 and the emitted light of the fluorescent materials 31.

The reflection film 51, the p-side interconnection layer 21, and the n-side interconnection layer 22 are simultaneously formed on a common metal film 60 shown in FIG. 4 by, for example, a plating method.

The reflection film 51, the p-side interconnection layer 21, and the n-side interconnection layer 22 include, for example, a copper film. The copper film is formed on the metal film 60, which is formed on the insulating film 18, by the plating method. The thickness of each of the reflection film 51, the p-side interconnection layer 21, and the n-side interconnection layer 22 is larger than the thickness of the metal film 60.

The metal film 60 includes a foundation metal film 61, an adhesive layer 62, and a seed layer 63 stacked in order from the insulating film 18 side.

The foundation metal film 61 is, for example, an aluminum film having high reflectivity to the emitted light of the light emitting layer 13.

The seed layer 63 is a copper film for depositing copper through plating. The adhesive layer 62 is, for example, a titanium film excellent in wettability to both of aluminum and copper.

In a region adjacent to the side surface 15c of the semiconductor layer 15, a plating film (a copper film) is not formed on the metal film 60. The reflection film 51 may be formed by the metal film 60. The reflection film 51 includes at least the aluminum film 61. Therefore, the reflection film 51 has high reflectance to the emitted light of the light emitting layer 13 and the emitted light of the fluorescent materials 31.

The foundation metal film (the aluminum film) 61 is also left under the p-side interconnection layer 21 and the n-side interconnection layer 22. Therefore, the aluminum film 61 is formed to expand in a most region on the second surface side of the semiconductor layer 15. Consequently, it is possible to increase an amount of light traveling to the fluorescent material layer 30 side.

A p-side metal pillar 23 is provided on the surface on the opposite side of the semiconductor layer 15 in the p-side interconnection layer 21. A p-side interconnection section 41 includes the p-side interconnection layer 21 and the p-side metal pillar 23.

An n-side metal pillar 24 is provided on the surface on the opposite side of the semiconductor layer 15 in the n-side interconnection layer 22. An n-side interconnection section 43 includes the n-side interconnection layer 22 and the n-side metal pillar 24.

A resin layer 25 is provided as an insulating layer between the p-side interconnection section 41 and the n-side interconnection section 43. The resin layer 25 is provided on a side surface 41 of the p-side interconnection section 41 and the side surface of the n-side interconnection section 43.

The resin layer 25 is provided between the p-side metal pillar 23 and the n-side metal pillar 24 to be set in contact with the side surface of the p-side metal pillar 23 and the side surface of the n-side metal pillar 24. The resin layer 25 is filled between the p-side metal pillar 23 and the n-side metal pillar 24.

The resin layer 25 is provided between the p-side interconnection layer 21 and the n-side interconnection layer 22, between the p-side interconnection layer 21 and the reflection film 51, and between the n-side interconnection layer 22 and the reflection film 51. The resin layer 25 is provided around the p-side metal pillar 23 and around the n-side metal pillar 24 and covers the side surface of the p-side metal pillar 23 and the side surface of the n-side metal pillar 24.

The resin layer 25 is also provided under a region (a chip outer circumferential section) adjacent to the side surface 15c of the semiconductor layer 15 and covers the reflection film 51.

The end portion (the surface) on the opposite side of the p-side interconnection layer 21 in the p-side metal pillar 23 is exposed from the resin layer 25 and functions as a p-side outer terminal 23a connectable to an external circuit such as a mounting substrate. The end portion (the surface) on the opposite side of the n-side interconnection layer 22 in the n-side metal pillar 24 is exposed from the resin layer 25 and functions as an n-side outer terminal 24a connectable to the external circuit such as the mounting substrate. The p-side outer terminal 23a and the n-side outer terminal 24a are joined to pads of the mounting substrate via, for example, solder or a conductive joining material.

As shown in FIG. 2B, the p-side outer terminal 23a and the n-side outer terminal 24a are formed side by side spaced apart from each other in the same plane of the resin layer 25. The p-side outer terminal 23a is formed in, for example, a rectangular shape. The n-side outer terminal 24a is formed in a shape obtained by cutting out two corners in a rectangle having the same size as the rectangle of the p-side outer terminal 23a. Consequently, the polarities of the outer terminals can be distinguished. The n-side outer terminal 24a may be formed in the rectangular shape and the p-side outer terminal 23a may be formed in the shape obtained by cutting out the corners of the rectangle.

The space between the p-side outer terminal 23a and the n-side outer terminal 24a is larger than the space between the p-side interconnection layer 21 and the n-side interconnection layer 22 on the insulating film 18. The space between the p-side outer terminal 23a and the n-side outer terminal 24a is set larger than the spread of the solder during mounting. Consequently, it is possible to prevent a short circuit between the p-side outer terminal 23a and the n-side outer terminal 24a through the solder.

On the other hand, the space between the p-side interconnection layer 21 and the n-side interconnection layer 22 can be reduced to a limit in a process. Therefore, the area of the p-side interconnection layer 21 and the contact area of the p-side interconnection layer 21 and the p-side metal pillar 23 can be increased. Consequently, it is possible to facilitate radiation of the heat of the light emitting layer 13.

The area of the p-side interconnection layer 21 in contact with the p-side electrode 16 through the plurality of vias 21a is larger than the area of the n-side interconnection layer 22 in contact with the n-side electrode 17 through the via 22a. Consequently, it is possible to uniformalize the distribution of an electric current flowing to the light emitting layer 13.

The area of the n-side interconnection layer 22 expanding on the insulating film 18 can be set larger than the area of the n-side electrode 17. The area of the n-side metal pillar 24 (the area of the n-side outer terminal 24a) provided on the n-side interconnection layer 22 can be set larger than the area of the n-side electrode 17. Consequently, it is possible to reduce the area of the n-side electrode 17 while securing the area of the n-side outer terminal 24a sufficient for mounting with high reliability. That is, it is possible to reduce the area of the portion 15f not including the light emitting layer 13 in the semiconductor layer 15 and increase the area of the portion (the light emitting region) 15e including the light emitting layer 13 to improve an optical output.

The first semiconductor layer 11 is electrically connected to the n-side metal pillar 24 via the n-side electrode 17 and the n-side interconnection layer 22. The second semiconductor layer 12 is electrically connected to the p-side metal pillar 23 via the p-side electrode 16 and the p-side interconnection layer 21.

The thickness of the p-side metal pillar 23 (the thickness in a connecting direction of the p-side interconnection layer 21 and the p-side outer terminal 23a) is larger than the thickness of the p-side interconnection layer 21. The thickness of the n-side metal pillar 24 (the thickness in a connecting direction of the n-side interconnection layer 22 and the n-side outer terminal 24a) is larger than the thickness of the n-side interconnection layer 22. The thickness of each of the p-side metal pillar 23, the n-side metal pillar 24, and the resin layer 25 is larger than the thickness of the semiconductor layer 15.

An aspect ratio (a ratio of thickness to a plane size) of the metal pillars 23 and 24 may be not less than 1 or may be less than 1. That is, the thickness of the metal pillars 23 and 24 may be larger than or may be smaller than the plane size thereof.

The thickness of the supporting body 100 including the p-side interconnection layer 21, the n-side interconnection layer 22, the p-side metal pillar 23, the n-side metal pillar 24, and the resin layer 25 may be larger than the thickness of the light emitting element (an LED chip) including the semiconductor layer 15, the p-side electrode 16, and the n-side electrode 17.

The semiconductor layer 15 is formed on the substrate by an epitaxial growth method. In the example shown in FIG. 1, the substrate is removed after the supporting body 100 is formed. The semiconductor layer 15 does not include the substrate on the rough surface 15a side. The semiconductor layer 15 is supported by the supporting body 100 made of a composite of the metal pillars 23 and 24 and the resin layer 25 rather than by the rigid tabular substrate.

As the material of the p-side interconnection section 41 and the n-side interconnection section 43, for example, copper, gold, nickel, and silver can be used. Among these kinds of metal, if copper is used, it is possible to improve satisfactory thermal conductivity, high migration resistance, and adhesion to an insulating material.

The resin layer 25 reinforces the p-side metal pillar 23 and the n-side metal pillar 24. As the resin layer 25, it is desired to use resin having a coefficient of thermal expansion same as or close to the coefficient of thermal expansion of the mounting substrate. Examples of such a resin layer 25 include resin mainly containing epoxy resin, resin mainly containing silicone resin, and fluorocarbon resin.

A light absorbing agent, a light reflecting agent, a light scattering agent, or the like is included in resin functioning as a base in the resin layer 25. The resin layer 25 has a light blocking property or reflectivity to the light of the light emitting layer 13. Consequently, it is possible to suppress light leakage from the side surface and the mounting surface side of the supporting body 100.

Stress due to the solder or the like for joining the p-side outer terminal 23a and the n-side outer terminal 24a to the pads of the mounting substrate is applied to the semiconductor layer 15 by a heat cycle during mounting of the semiconductor light emitting device. The p-side metal pillar 23, the n-side metal pillar 24, and the resin layer 25 absorb and reduce the stress. In particular, it is possible to improve a stress reducing effect by using the resin layer 25 more flexible than the semiconductor layer 15 as a part of the supporting body 100.

The reflection film 51 is separated from the p-side interconnection section 41 and the n-side interconnection section 43. Therefore, the stress applied to the p-side metal pillar 23 and the n-side metal pillar 24 during the mounting is not transmitted to the reflection film 51. Therefore, it is possible to suppress peeling of the reflection film 51. It is possible to suppress stress applied to the side surface 15c side of the semiconductor layer 15.

The substrate used for formation (crystal growth) of the semiconductor layer 15 is removed from the semiconductor layer 15. Consequently, the semiconductor light emitting device is reduced in height. Micro irregularities can be formed on a surface from which the substrate is removed in the semiconductor layer 15. It is possible to attain improvement of light extraction efficiency. For example, the micro irregularities are formed by wet etching using alkali solution. The rough surface 15a is formed on a light extraction side of the semiconductor layer 15. A total reflection component is reduced by the rough surface 15a. It is possible to improve the light extraction efficiency.

After the rough surface 15a is formed, the fluorescent material layer 30 is formed on the rough surface 15a via the insulating film 19. The insulating film 19 functions as an adhesive layer that improves adhesion of the semiconductor layer 15 and the fluorescent material layer 30. The insulating film 19 is, for example, a silicon oxide film or a silicon nitride film.

The fluorescent material layer 30 has a structure in which the plurality of particle-like fluorescent materials 31 are dispersed in the transmissive layer 32. The transmissive layer 32 is a transparent resin layer mainly containing, for example, silicone resin.

The fluorescent material layer 30 is not formed to extend over to the second surface side of the semiconductor layer 15, the peripheries of the metal pillars 23 and 24, and the side surface of the supporting body 100. The side surface of the fluorescent material layer 30 and the side surface of the supporting body 100 (the side surface of the resin layer 25) are aligned.

That is, the semiconductor light emitting device of the embodiment is an extremely small semiconductor light emitting device of a chip-size package structure. Therefore, for example, when the semiconductor light emitting device is applied to a lighting lamp and the like, flexibility of lamp design is improved.

The fluorescent material layer 30 is not uselessly formed on the mounting surface side where light is not extracted to the outside. It is possible to reduce costs. The heat of the light emitting layer 13 can be radiated to the mounting substrate side via the p-side interconnection layer 21, the n-side interconnection layer 22, and the thick metal pillars 23 and 24 expanding on the second surface side. Although small in size, the semiconductor light emitting device is excellent in heat radiation.

In general flip-chip mounting, after an LED chip is mounted on a mounting substrate via bumps or the like, a fluorescent material layer is formed to cover the entire chip. Alternatively, resin is under-filled among the bumps.

On the other hand, according to the embodiment, in the state before the mounting, the resin layer 25 different from the fluorescent material layer 30 is provided around the p-side metal pillar 23 and around the n-side metal pillar 24. Characteristics suitable for a stress reduction can be imparted to the mounting surface side. Since the resin layer 25 is already provided on the mounting surface side, the under-fill after the mounting is unnecessary.

On the first surface (rough surface) 15a side, an optical layer preferentially designed for light extraction efficiency, color conversion efficiency, luminous intensity distribution efficiency, and the like is provided. On the mounting surface side, a layer preferentially designed for the stress reduction during the mounting and characteristics of a supporting body replacing the substrate is provided. For example, a filler such as silica particles can be filled in the resin layer 25 at high density to adjust the resin layer 25 to hardness appropriate as the supporting body.

Light emitted from the light emitting layer 13 to the rough surface 15a side is made incident on the fluorescent material layer 30. A part of the light excites the fluorescent materials 31. As mixed light of the light of the light emitting layer 13 and the light of the fluorescent materials 31, for example, white light is simulatively obtained.

When the substrate is present on the rough surface 15a, light not made incident on the fluorescent material layer 30 and leaking to the outside from the side surface of the substrate occurs. That is, light having strong tint in the light of the light emitting layer 13 leaks from the side surface of the substrate. The light could cause color breakup and color unevenness such as a phenomenon in which, when the fluorescent material layer 30 is viewed from above, a ring of blue light is seen on the outer edge side.

On the other hand, according to the embodiment, the substrate is absent between the rough surface 15a and the fluorescent material layer 30. Therefore, it is possible to prevent the color breakup and the color unevenness due to the leak of the light having the strong tint in the light of the light emitting layer 13 from the substrate side surface.

According to the embodiment, as shown in FIG. 3, the reflection film 51 is provided on the side surface 15c of the first semiconductor layer 11 via the insulating film 18. Light traveling from the light emitting layer 13 to the side surface 15c of the first semiconductor layer 11 is reflected on the reflection film 51 and does not leak to the outside. Further, the substrate is absent on the rough surface 15a side. It is possible to prevent color breakdown and color unevenness due to a light leak from the side surface side of the semiconductor light emitting device.

Further, according to the embodiment, a transmissive layer (a first transmissive layer) 11a is provided on the side of the first semiconductor layer 11. The transmissive layer 11a is provided in a region adjacent to the side surface 15c of the first semiconductor layer 11. The transmissive layer 11a is an inorganic material layer and is formed of, for example, a material same as the first semiconductor layer 11. That is, a layer formed of the same material (e.g., a layer containing GaN) is divided into the first semiconductor layer 11 and the transmissive layer 11a by the reflection film 51.

As shown in FIG. 2A, the reflection film 51 continuously surrounds the side surface 15c of the first semiconductor layer 11 via the insulating film 18. The transmissive layer 11a continuously surrounds the side surface 15c of the first semiconductor layer 11 via the reflection film 51 and the insulating film 18.

The insulating film 18 is provided between the first semiconductor layer 11 and the reflection film 51 and between the transmissive layer 11a and the reflection layer 51. The insulating film 18 covers the surface of the reflection film 51 that divides the first semiconductor layer 11 and the transmissive layer 11a. The insulating film 18 is also provided between the reflection film 51 and the fluorescent material layer 30.

A distal end portion of a portion that divides the first semiconductor layer 11 and the transmissive layer 11a in the reflection film 51 projects further to the fluorescent material layer 30 side than the rough surface 15a and an upper surface 91 of the transmissive layer 11a.

The resin layer 25 is also provided under the transmissive layer 11a. A reflection film (a first reflection film) 27 is provided between the resin layer 25 and the transmissive layer 11a. The reflection film 27 is provided in contact with the lower surface of the transmissive layer 11a. The insulating film 18 is provided between the reflection film 27 and the resin layer 25. The insulating film 18 is provided between the first reflection film 27 and the second reflection film 51.

The reflection film 27 is a film of a type same as, for example, the n-side electrode 17 or the p-side electrode 16, which is a metal film. The reflection film 27 contains, for example, at least any one of silver and aluminum. As shown in FIG. 2A, the reflection film 27 continuously surrounds the n-side electrode 17.

A stacked film of the transmissive layer 11a and the reflection film 27 is provided in a region around the side surface 15c of the first semiconductor layer 11.

The refractive index (the absolute refractive index) of the transmissive layer 11a is higher than the refractive index (the absolute refractive index) of the transmissive layer 32 of the fluorescent material layer 30. The refractive index of the transmissive layer 11a is not less than 1.7.

The surface roughness of the surface 91 on the fluorescent material layer 30 side in the transmissive layer 11a or the interface 91 between the transmissive layer 11a and the transmissive layer 32 of the fluorescent material layer is smaller than the surface roughness of the rough surface 15a of the first semiconductor layer 11. Parameters representing the surface roughness are arithmetic mean roughness, maximum height, ten-point average roughness, and the like.

The surface 91 on the fluorescent material layer 30 side in the transmissive layer 11a is a substantially flat surface in comparison with the rough surface 15a of the first semiconductor layer 11. After the substrate used for the growth of the semiconductor layer 15 is removed, in a state in which the upper surface of the transmissive layer (the GaN layer) 11a in a chip outer region is covered with a mask, roughening treatment (frost treatment) is applied to the upper surface of the first semiconductor layer (the GaN layer) in a chip region.

The fluorescent materials are excited by the light of the light emitting layer 13 to isotropically emit light to the periphery of the fluorescent materials. Light traveling to the transmissive layer 11a side in the emitted light of the fluorescent materials in a chip outer peripheral region is reflected on the upper surface 91 of the transmissive layer 11a (the interface 91 between the transmissive layer 11a and the fluorescent material layer 30) or the reflection film 27.

The transmissive layer (transparent resin) 32 of the fluorescent material layer 30 and the transmissive layer (the GaN layer) 11a have different refractive indexes. For example, whereas the refractive index of the GaN layer is approximately 2.5, the refractive index of the transparent resin (e.g., silicone resin) is approximately 1.5. The upper surface 91 of the transmissive layer 11a (the interface 91 between the transmissive layer 11a and the fluorescent material layer 30) is a substantially flat surface for the wavelength of the light (florescent light) made incident on the surface 91.

Therefore, light made incident on the upper surface 91 of the transmissive layer 11a at a relatively large incident angle (a shallow angle) is reflected on the upper surface 91 of the transmissive layer 11a (the interface 91 between the transmissive layer 11a and the fluorescent material layer 30) as indicated by an arrow A in FIG. 3.

Light made incident on the upper surface 91 of the transmissive layer 11a at a relatively small incident angle (a deep angle) is refracted on the upper surface (the interface) 91 and made incident on the transmissive layer 11a as indicated by an arrow B in FIG. 3. The incident light is reflected on the reflection film 27 under the transmissive layer 11a and returned to the fluorescent material layer 30 side.

The transmissive layer (the GaN Layer) 11a has a refractive index higher than the refractive index of the transmissive layer (the resin layer) 32 of the fluorescent material layer 30. Therefore, the light made incident on the surface 91 is made incident on the reflection film 27 at an angle closer to the perpendicular with respect to the surface of the reflection film 27. The reflectance on the reflection film 27, which is a metal film, is higher as the incident angle of the light is closer to the perpendicular with respect to the surface of the reflection film 27.

As described above, according to the embodiment, the light traveling downward to the supporting body 100 side in the emitted light of the fluorescent materials in the chip outer region (an end region) in the semiconductor light emitting device can be reflected on the upper surface 91 of the transmissive layer or the reflection film 27 and returned to the fluorescent material layer 30 side.

Therefore, it is possible to prevent a loss due to absorption of the emitted light of the fluorescent materials by the resin layer 25 of the supporting body 100 in the chip outer region of the semiconductor light emitting device and improve light extraction efficiency from the fluorescent material layer 30 side.

The insulating film 18 provided between the reflection film 51 and the side surface 15c of the semiconductor layer 11 prevents metal contained in the reflection film 51 from diffusing to the semiconductor layer 11. Consequently, it is possible to prevent metal contamination by, for example, GaN contained in the semiconductor layer 11. It is possible to prevent deterioration of the semiconductor layer 11.

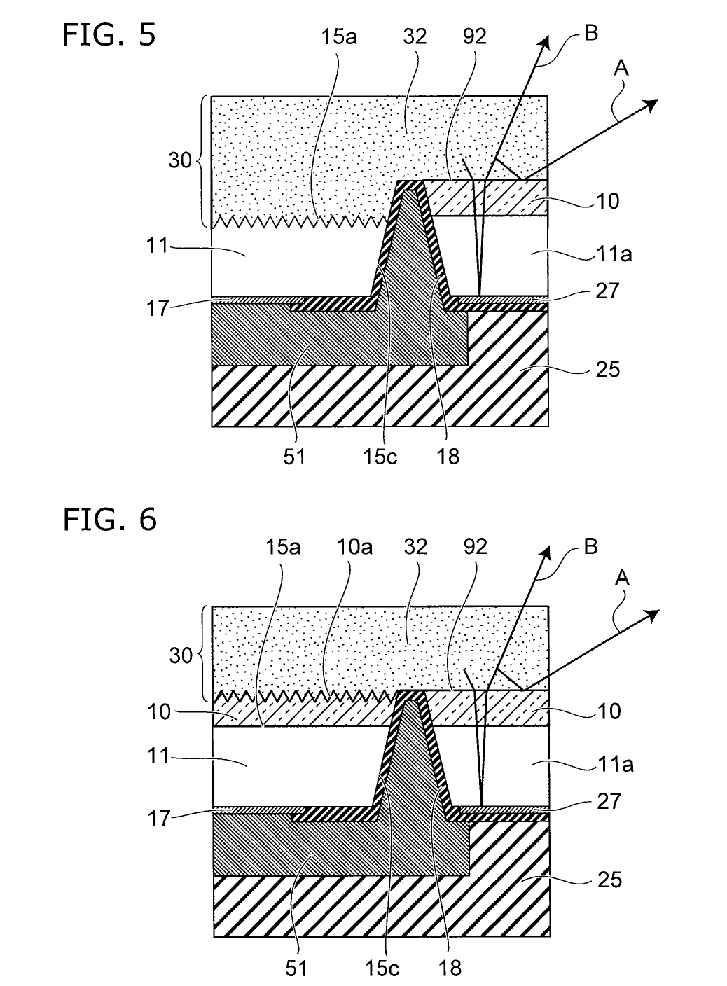

FIG. 5 is an enlarged schematic sectional view of a portion corresponding to FIG. 3 in a semiconductor light emitting device of another embodiment.

In an example shown in FIG. 5, a part of the substrate 10 used for crystal growth (epitaxial growth) of the semiconductor layers (the GaN layers) 11 and 11a is left on the transmissive layer (the GaN layer) 11a in the chip outer region. The substrate 10 is removed from the semiconductor layer 11 in the chip region. The substrate 10 is absent on the rough surface 15a.

The substrate 10 is, for example, a sapphire substrate or a silicon carbide (SiC) substrate transparent to emitted light of the light emitting layer 13 and emitted light of the fluorescent materials 31. The substrate 10 left in the chip outer region is ground thinner than when the semiconductor layer 15 is grown.

A stacked body of the transmissive layer (the GaN layer) 11a and the substrate 10 is provided between the resin layer 25 and the fluorescent material layer 30 as a transmissive layer in the chip outer region.

The refractive index (the absolute refractive index) of the substrate 10 is higher than the refractive index (the absolute refractive index) of the transmissive layer 32 of the fluorescent material layer 30. The refractive index of the substrate 10 is not less than 1.7.

The surface roughness of a surface 92 on the fluorescent material layer 30 side in the substrate 10 or an interface 92 between the substrate 10 and the transmissive layer 32 of the fluorescent material layer is smaller than the surface roughness of the rough surface 15a of the semiconductor layer 11. The surface 92 on the fluorescent material layer 30 side in the substrate 10 is a substantially flat surface in comparison with the rough surface 15a of the first semiconductor layer 11. The upper surface 92 of the substrate 10 (the interface 92 between the substrate 10 and the fluorescent material layer 30) is a substantially flat surface for the wavelength of light (fluorescent light) made incident on the surface 92.

Therefore, light made incident on the upper 92 of the substrate 10 at a relatively large incident angle (a shallow angle) is reflected on the upper surface 92 of the substrate 10 (the interface 92 between the substrate 10 and the fluorescent material layer 30) as indicated by an arrow A in FIG. 5.

Light made incident on the upper surface 92 of the substrate 10 at a relatively small incident angle (a deep angle) is refracted on the upper surface (the interface) 92 and made incident on the substrate 10 as indicated by an arrow B in FIG. 5. The incident light is reflected on the reflection film 27 under the transmissive layer 11a and returned to the fluorescent material layer 30 side.

The substrate 10 has a refractive index higher than the refractive index of the transmissive layer (the resin layer) 32 of the fluorescent material layer 30. Therefore, the light made incident on the surface 92 is made incident on the reflection film 27 at an angle closer to the perpendicular with respect to the surface of the reflection film 27. The reflectance of the reflection film 27 is increased.

As described above, in the embodiment shown in FIG. 5 as well, it is possible to prevent a loss due to absorption of the emitted light of the fluorescent materials by the resin layer 25 of the supporting body 100 in the chip outer region (the end region) of the semiconductor light emitting device and improve light extraction efficiency from the fluorescent material layer 30 side.

FIG. 6 is an, enlarged schematic sectional view of a portion corresponding to FIG. 3 in a semiconductor light emitting device of still another embodiment.

In an example shown in FIG. 6, the substrate 10 is also left on the upper surface 15a of the first semiconductor layer 11 in the chip region in the structure shown in FIG. 5. Micro irregularities are formed on an upper surface 10a of the substrate 10 (a surface 10a on the fluorescent material layer 30 side) to roughen the upper surface 10a. The surface roughness of the upper surface 92 of the substrate 10 in the chip outer region is smaller than the surface roughness of the upper surface (a rough surface) 10a of the substrate 10 in the chip region.

In a state in which the upper surface 92 of the substrate 10 in the chip outer region is covered with the mask, roughening treatment (frost treatment) is applied to the upper surface 10a of the substrate 10 in the chip region.

It is possible to reduce a total reflection component and improve light extraction efficiency with the upper surface (the rough surface) 10a of the substrate 10 on a light extraction side in the chip region.

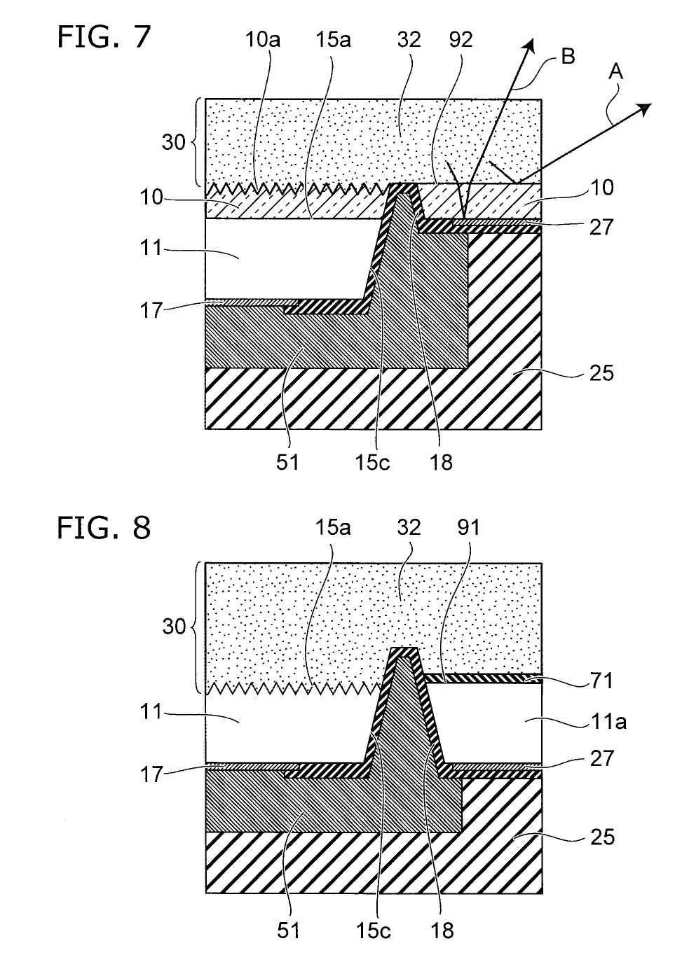

A transmissive layer (a first transmissive layer) having a refractive index different from the refractive index of a transmissive layer (a second transmissive layer) of the fluorescent material layer 30 and provided in the chip outer region may be only a transparent substrate 10 as shown in FIG. 7.

The reflection film (the metal film) 27 is provided on the lower surface of the transparent substrate 10.

In the structure shown in FIG. 3, as shown in FIG. 8, an insulating film 71 may be provided between the transmissive layer (the GaN layer) 11a in the chip outer region and the transmissive layer (the transparent resin layer) 32 of the fluorescent material layer 30. The insulating film 71 is an inorganic film such as a silicon oxide film or a silicon nitride film and is excellent in adhesion between the GaN layer 11a and the transparent resin layer 32.

In the embodiments described above, the optical layer provided on the rough surface 15a side of the semiconductor layer 15 is not limited to the fluorescent material layer and may be a scattering layer. The scattering layer includes a plurality of particle-like scattering materials (e.g., titanium compounds), which scatter the emitted light of the light emitting layer 13, and a transmissive layer (e.g., a transparent resin layer) in which a plurality of scattering materials are integrated to transmit the emitted light of the light emitting layer 13.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor light emitting device comprising:
a stacked body including a first layer having a rough surface, a second layer, and a light emitting layer provided between the first layer and the second layer;
a first electrode provided on the first layer;
a second electrode provided on the second layer;
a first interconnection section provided on an opposite side of the rough surface in the stacked body and connected to the first electrode;
a second interconnection section provided on the opposite side of the rough surface in the stacked body and connected to the second electrode;
an insulating layer provided on a side surface of the first interconnection section and a side surface on the second interconnection section;
a first transmissive layer provided on a side of the stacked body;
a first reflection film provided between the first transmissive layer and the insulating layer; and
a second transmissive layer provided on the rough surface of the first layer and on the first transmissive layer, and including a plurality of particles,
surface roughness of a surface on the second transmissive layer side of the first transmissive layer being smaller than surface roughness of the rough surface of the first layer.

2. The device according to claim 1, wherein a refractive index of the first transmissive layer is higher than a refractive index of the second transmissive layer.

3. The device according to claim 1, wherein the particles are fluorescent material particles excited by emitted light of the light emitting layer to emit light having wavelength different from wavelength of the emitted light of the light emitting layer.

4. The device according to claim 1, further comprising a second reflection film provided between a side surface of the stacked body and the first transmissive layer.

5. The device according to claim 4, further comprising an insulating film provided between the side surface of the stacked body and the second reflection film.

6. The device according to claim 4, wherein the second reflection film includes an aluminum film.

7. The device according to claim 1, wherein the first transmissive layer includes a layer of a material same as the first layer.

8. The device according to claim 4, wherein a layer is divided into the first layer and the first transmissive layer by the second reflection film.

9. The device according to claim 1, wherein the first layer includes:
a first semiconductor layer; and
a substrate provided between the first semiconductor layer and the second transmissive layer, and including the rough surface.

10. The device according to claim 9, wherein the first semiconductor layer is crystal-grown on the substrate.

11. The device according to claim 1, wherein the first transmissive layer is an inorganic material layer.

12. The device according to claim 1, wherein the first reflection film is a film of a material of a same type as the first electrode or the second electrode.

13. The device according to claim 1, wherein the first reflection film contains at least any one of silver and aluminum.

14. The device according to claim 1, wherein the insulating layer is a resin layer.

15. The device according to claim 1, wherein the first transmissive layer includes:
a semiconductor layer; and
a substrate provided between the semiconductor layer and the second transmissive layer.

16. The device according to claim 15, wherein the semiconductor layer is crystal-grown on the substrate.

17. The device according to claim 1, wherein
the first layer includes:
a first semiconductor layer; and
a first substrate provided between the first semiconductor layer and the second transmissive layer, and including the rough surface, and
the first transmissive layer includes:
a second semiconductor layer; and
a second substrate provided between the second semiconductor layer and the second transmissive layer.

18. The device according to claim 17, wherein
the first substrate and the second substrate are a same substrate, and
the first semiconductor layer and the second semiconductor layer is a same semiconductor layer crystal-grown on the substrate.

19. The device according to claim 18, further comprising a second reflection film dividing the first substrate and the second substrate, and dividing the first semiconductor layer and the second semiconductor layer.

20. A semiconductor light emitting device comprising:
a stacked body including a first layer having a first surface, a second layer, and a light emitting layer provided between the first layer and the second layer, the stacked body not including a substrate on the first surface side;
a first electrode provided on the first layer;
a second electrode provided on the second layer;
a first interconnection section provided on an opposite side of the first surface in the stacked body and connected to the first electrode;
a second interconnection section provided on the opposite side of the first surface in the stacked body and connected to the second electrode;
an insulating layer provided on a side surface of the first interconnection section and a side surface on the second interconnection section;
a first transmissive layer provided on a side of the stacked body;
a first reflection film provided between the first transmissive layer and the insulating layer;
a second transmissive layer provided on the first surface of the first layer and on the first transmissive layer, and including a plurality of particles; and
a transmissive substrate provided between the first transmissive layer and the second transmissive layer.
